(19) United States
(12) Patent Application Publication
(10) Pub. No.: US 2010/0181596 A1
(43) Pub. Date: Jul. 22, 2010

(54) SEMICONDUCTOR DEVICE AND MANUFACTURING METHOD THEREOF

(76) Inventors: Satoshi Suzuki, Kyoto (JP); Hiroyoshi Ogura, Kyoto (JP)

Correspondence Address: MCDERMOTT WILL & EMERY LLP, 600 13TH STREET, NW, WASHINGTON, DC, 20005-3096, US

(21) Appl. No.: 12/689,627

(22) Filed: Jan. 19, 2010

(30) Foreign Application Priority Data
Jan. 19, 2009 (JP) 2009-008749

(51) Int. Cl. H01L 27/12; H01L 29/739; H01L 21/331; H01L 29/78; H01L 21/86

(52) U.S. Cl. 257/139; 257/347; 438/135; 257/335; 438/151; 257/E21.704; 257/E21.382; 257/E21.409; 257/E27.112; 257/E29.197; 257/E29.255

(57) ABSTRACT

A high voltage horizontal IGBT, which is an aspect of a semiconductor device relating to the present invention, has a buffer region formed in an SOI substrate and extending from a surface of the SOI substrate to a surface of a buried oxide film. An interface between the buffer region and a drift region is positioned equally in a vicinity of a bottom of the buffer region and in a vicinity of a surface of the buffer region or shifted toward a body region in the vicinity of the bottom of the buffer region compared to that in the vicinity of the surface of the buffer region. With this structure, a concentration of electric field in the vicinity of the bottom of the buffer region is moderated, whereby a collector-emitter breakdown voltage can further be increased.

### CROSS-REFERENCE TO RELATED APPLICATION

The disclosure of Japanese Patent Application No. 2009-008749 filed Jan. 19, 2009 including specification, drawings and claims is incorporated herein by reference in its entirety.

### BACKGROUND OF THE INVENTION

1. Field of the Invention

The present invention relates to a semiconductor device having a high voltage horizontal MOSFET (metal oxide semiconductor field effect transistor) or a high voltage horizontal IGBT (insulated gate bipolar transistor) on an SOI (silicon on insulator) substrate and a manufacturing method thereof.

2. Description of the Related Art

Recently, semiconductor devices containing low voltage operation integrated circuits (ICs) in combination with high voltage elements have been utilized in various applications. For example, a semiconductor device used in a drive circuit of a plasma display contains a high voltage horizontal MOSFET or a high voltage horizontal IGBT to construct an integrated circuit.

In a high voltage horizontal MOSFET, a drain region and a source region are formed such that a depletion layer (diffusion layer) between the drain region and the source region, or a PN junction, has an elongated or oval shape extending towards the source region in a plane view. The elongated or oval PN junction means that a longitudinal end of the drain region is semicircular. A problem is that an electric field concentrates at this semicircular, the longitudinal end of the drain region when a positive voltage in relation to the source region is applied to the drain region, deteriorating drain-source voltage properties.

In order to resolve the problem, Japanese Laid-Open Patent Application Publication No. H8-070118 describes a semiconductor device in which an elongated drain region of a second conductivity type is formed in a semiconductor substrate of a first conductivity type and an elongated drain electrode is formed on the drain region via an elongated, high concentration drain contact region of the second conductivity type. This semiconductor device is characterized by the fact that the drain electrode extends in a longitudinal direction and a distance between a longitudinal end of the drain electrode and the drain contact region is greater than a distance between a crosswise end of the drain electrode and the drain contact region.

The above structure yields a field plate effect, moderating an electric field concentration at the longitudinal end of the drain region, improving drain-source voltage properties.

On the other hand, a high voltage horizontal IGBT using an SOI substrate is provided with a buffer region formed next to a drift region of the high voltage horizontal IGBT and having an impurity concentration higher than an impurity concentration of the drift region in order to adjust an efficiency of hole injection from a collector region. The collector region (collector contact region) is formed in a surface portion of the buffer region. A bottom of the buffer region reaches a buried oxide film constituting the SOI substrate.

A structure of a conventional high voltage horizontal IGBT is described in detail hereafter with reference to FIGS. 7A and 7B. FIG. 7A is a cross-sectional view showing a conventional high voltage horizontal IGBT. The vertical direction in FIG. 7A corresponds to the vertical direction of the conventional high voltage horizontal IGBT and the transversal direction in FIG. 7A corresponds to the transversal direction of the conventional high voltage horizontal IGBT. FIG. 7A is a schematic illustration in which scales in the vertical and transversal directions are not equal.

A buried oxide film 702 is formed on a support substrate 701 of a P-type silicon monocrystal, which is a substrate of a high voltage horizontal IGBT. An SOI layer 703 of a P-type silicon monocrystal is formed on a surface of the buried oxide film 702.

The support substrate 701 and the SOI layer 703 are separate silicon monocrystal layers. They are bonded together via the buried oxide film 702 to form a single substrate. The substrate having this structure is termed the SOI substrate. The SOI layer 703 constituting an upper layer of the SOI substrate has a specific resistance of approximately 1 to 10Ω·cm. The SOI substrate is formed, for example, by a bonded process in which two silicon monocrystal substrates are annealed via a surface oxide film on either substrate and etched or polished to a thickness of the SOI layer 703.

A P-type impurity is ion-implanted in the SOI layer 703 from above the SOI substrate to form a body region 705. An N-type impurity is ion-implanted in a relatively low concentration in a region of the SOI layer 703 next to the body region 705 to form a drift region 704. Furthermore, an N-type impurity is ion-implanted in a relatively high concentration in a surface portion of the body region 705 to form an emitter region 706.

An N-type impurity is ion-implanted in a region of the SOI layer 703 next to the drift region 704 to a concentration higher than that in the drift region 704. Then, a buffer region 713 is formed through high temperature heat treatment for example at 1000° C. to 1250° C. The buffer region 713 is located at an opposite position to the body region 705 in relation to the drift region 704.

An N-type impurity is ion-implanted in a surface portion of the SOI layer 703 corresponding to the buffer region 713. For example, when an N-type impurity is ion-implanted with a dose amount of approximately 5×10¹³ to 5×10⁴ cm⁻² and with an acceleration energy of approximately 40 keV, the implanted N-type impurity is embedded in a vicinity of the surface of the SOI layer 703, not in a vicinity of the bottom of the SOI layer 703. Here, the bottom of the SOI layer 703 corresponds to the surface of the buried oxide film 702.

FIG. 7B is a graphical representation showing an N-type impurity concentration distribution in the buffer region 713 along a line A-A shown in FIG. 7A. In the concentration distribution chart of FIG. 7B, a depth in the buffer region 713 along the line A-A from the surface to the bottom of the buffer region 713 is plotted as ordinate with an uppermost surface of the buffer region 713 being at the coordinates of zero and the N-type impurity concentration is plotted as abscissa. Here, the bottom of the region 713 corresponds to the surface of the buried oxide film 702.

As shown in FIG. 7B, it is understood that the N-type impurity concentration in the buffer region 713 is higher in the vicinity of the surface than in the vicinity of the bottom. For example, the N-type impurity concentration at a depth B corresponding to the vicinity of the surface of the buffer region 713 is higher than that at a depth C corresponding to the vicinity of the bottom of the buffer region 713, and there is a difference N0 in concentration between them.

After the buffer region 713 is formed, a P-type impurity is ion-implanted in a relatively high concentration to form a collector region 714 in a surface portion of the buffer region 713. The collector region 714 makes no direct contact with the drift region 704.

Furthermore, for example, a LOCOS (local oxidation of silicon) oxide film 707 serving as an insulating layer is formed on a part of the surface of the SOI layer 703 by local thermal oxidation. In FIG. 7A, the LOCOS oxide film is formed at two positions. A first LOCOS oxide film 707a covers a part of the surface of the buffer region 713 and a part of the surface of the drift region 704. A second LOCOS oxide film 707b covers a part of the surface of the body region 705. The second LOCOS oxide film 707b makes no contact with the emitter region 706 formed on the surface of the body region 705.

Then, a gate oxide film 708 as a gate insulating film is formed between the emitter region 706 and the first LOCOS oxide film 707a to cover a part of the surface of the drift region 704 and a part of the surface of the body region 705. The gate oxide film 708 makes contact with the first LOCOS oxide film 707a.

A polysilicon gate electrode 709 is formed on a surface of the gate oxide film 708.

The gate electrode 709 faces the body region 705 and the drift region 704 and is insulated from the SOI layer 703 by the gate oxide film 708.

An interlayer insulating film 710 is formed to cover surfaces of the gate electrode 709 and the first LOCOS oxide film 707a. An emitter electrode 711 and a collector electrode 712, which are metal electrodes, are formed on a surface of the interlayer insulating film 710. The emitter electrode 711 is electrically connected to the emitter region 706 and the collector electrode 712 is electrically connected to the collector region 714. The emitter electrode 711 and the collector electrode 712 are electrically separated.

In the above structure, for example, when a predetermined positive voltage is applied to the collector electrode 712 and a predetermined positive voltage is applied to the gate electrode 709 while 0V is applied to the emitter electrode 711 and the support substrate 701, a channel region is formed in the body region 705 and the high voltage horizontal IGBT is turned on. In other words, an electric current runs from the collector electrode 712 to the emitter electrode 711 via the buffer region 713, the drift region 704 and the channel region, and the high voltage horizontal IGBT operates as an electric field effect transistor.

### SUMMARY OF THE INVENTION

The high voltage horizontal IGBT having the above structure is in the OFF state wherein no electric current runs from the collector electrode 712 to the emitter electrode 711 while the channel region is not formed (for example while the gate voltage is 0V).

FIG. 7A also shows an equipotential line distribution when a positive voltage in relation to the emitter electrode 711 is applied to the collector electrode 712 in the above OFF state.

As shown in FIG. 7A, when the positive voltage described above is applied and a potential difference occurs between the collector electrode 712 and the emitter electrode 711, the drift region 704 and the body region 705 are depleted and a potential difference occurs in the drift region 704 in the transversal direction.

Within the buffer region 713 in the above state, because of the presence of a relatively high concentration of N-type impurity, no potential difference occurs and the potential is uniform in the buffer region 713. On the other hand, within the drift region 704 in which a relatively low concentration of N-type impurity is present, multiple equipotential lines occur in the transversal direction and they are adjacent (close) to each other.

Meanwhile, as explained with reference to FIG. 7B, the N-type impurity concentration in the buffer region 713 is higher in the vicinity of the surface than in the vicinity of the bottom as a result of a manufacturing process thereof. Therefore, the N-type impurity concentration distribution in the buffer region 713 is such that the N-type impurity concentration is decreased with depth in the buffer region 713 from the surface of the SOI layer 703 from which the ion implantation is performed to the bottom of the SOI layer 703. Here, the bottom of the SOI layer 703 corresponds to the surface of the buried oxide film 702 as described above.

As shown in FIG. 7B, the N-type impurity concentration distribution in the buffer region 713 also encompasses a concentration distribution resulting from factors other than a thermal diffusion of N-type impurity during a high temperature heat treatment. For example, as shown in a region S0 in FIG. 7B, it is understood that an uneven N-type impurity concentration distribution, namely segregation (pile up) occurs in the vicinity of the interface between the buffer region 713 and the buried oxide film 702 because of the aforementioned factors other than the thermal diffusion. Furthermore, as shown in a region S1 in FIG. 7B, it is understood that segregation also occurs in the uppermost surface portion of the buffer region 713 in the same manner as the above. In other words, the N-type impurity distribution in the buffer region 713 shown in FIG. 7B is a combination of the concentration distribution resulting from thermal diffusion and the concentration distribution resulting from segregation. The uppermost surface portion of the buffer region 713 corresponds to the bottom of the collector region 114 or first LOCOS oxide film 707a in the completed high voltage horizontal IGBT.

However, the concentration distribution resulting from segregation has minor influence on the N-type impurity concentration distribution in the buffer region 713 compared to the concentration distribution resulting from thermal diffusion. Therefore, the N-type impurity concentration distribution in the buffer region 713 is such that the N-type impurity concentration is decreased with depth in the buffer region 713 from the vicinity of the surface to the vicinity of the bottom.

FIG. 8A is a transversal cross-sectional view of the buffer region 713 at a line B-B in FIG. 7A (corresponding to a position B in FIG. 7B). FIG. 8B is a transversal cross-sectional view of the buffer region 713 at a line C-C in FIG. 7A (corresponding to a position C in FIG. 7B). The transversal direction in FIGS. 8A and 8B corresponds to the longitudinal direction of the buffer region 713. The body region 705 is located a left side in FIGS. 8A and 8B.

As shown in FIGS. 8A and 8B, the buffer region 713 is elongated toward the body region 705 in a plane view. The longitudinal end of the buffer region 713 is semicircular in a plane view. The longitudinal end of the buffer region 713 corresponds to the interface between the buffer region 713 and the drift region 704.

Furthermore, as shown in FIGS. 8A and 8B, it is understood that the radius of curvature (r1) of the semicircular portion of the buffer region 713 at the line B-B is larger than the radius of curvature (r2) of the semicircular portion of the buffer region 713 at the line C-C and the longitudinal end of the buffer region 713 at the line B-B protrudes toward the drift region 704 by a given distance D0 compared to the longitudinal end of the buffer region 713 at the line C-C.

In the buffer region 713 having the cross-sections as shown in FIGS. 8A and 8B, when a positive voltage in relation to the emitter electrode 711 is applied to the collector electrode 712, a potential difference occurs in the drift region 704. When a potential difference occurs in the drift region 704, the electric field concentrates at the part of the semicircular, longitudinal end of the buffer region 713 that has a smaller radius of curvature, for example at the semicircular end of the buffer region 713 at the line C-C.

As described above, a high voltage horizontal IGBT using an SOI substrate is provided with the buried oxide film 702 having high dielectric breakdown strength below the buffer region 713. Therefore, a problem is that the aforementioned electric field concentration more easily occurs in the vicinity of the bottom of the buffer region 713 compared to a high voltage horizontal IGBT provided with no buried oxide film 702.

FIG. 8C shows an electric field strength distribution along the transversal direction in the drift region 704 at the depths of the lines B-B and C-C shown in FIG. 8A. The electric field strength corresponds to a potential difference between equipotential lines (potential gradient).

As shown in FIG. 8C, it is understood that when an electric field concentration occurs in the vicinity of the bottom of the buffer region 713, the electric field strength in the vicinity of the interface between the buffer region 713 and the drift region 704 is higher in the vicinity of the bottom of the buffer region 713 (corresponding to a curve C0 in FIG. 8C) than in the vicinity of the surface of the buffer region 713 (corresponding to a curve C1 in FIG. 8C). The difference in electric field strength X between them determines a breakdown voltage between the collector electrode 712 and the emitter electrode 711, in other words a collector-emitter breakdown voltage.

In the future, higher collector-emitter breakdown voltage will be required in a high voltage horizontal IGBT using an SOI substrate. However, it is not easy to improve the collector-emitter breakdown voltage in the conventional high voltage horizontal IGBT as described above as a result of the manufacturing process.

The present invention is invented in order to resolve the above problem and the purpose of the present invention is to provide a semiconductor device allowing for a higher collector-emitter breakdown voltage and a manufacturing method of a semiconductor device.

In order to achieve the above purpose, the present invention utilizes the following technical means. First, a semiconductor device according to the present invention is supposed to be a semiconductor device comprising an SOI substrate, body region, emitter region, drift region, buffer region, collector region and gate electrode.

The SOI substrate has an insulating layer and a semiconductor layer of a first conductivity type provided on the insulating layer. The body region consisting of an impurity region of the first conductivity type is provided in the semiconductor layer. The emitter region consisting of an impurity region of a second conductivity type that is an opposite conductivity type to the first conductivity type is provided in a surface portion of the body region. The drift region consisting of a low concentration impurity region of the second conductivity type is provided in the semiconductor layer next to the body region. The buffer region consisting of a high concentration impurity region of the second conductivity type is provided in the semiconductor layer next to the drift region. The collector region consisting of an impurity region of the first conductivity type is provided in a surface portion of the buffer region. The gate electrode faces the body region and the drift region and is provided on the semiconductor layer via a gate insulating film.

The insulating layer is for example an oxide film consisting of oxidized silicon, the silicon being semiconductor. The semiconductor layer of the first conductivity type is for example a P-type silicon monocrystal layer. When the first conductivity type is P-type, the second conductivity type is N-type.

The buffer region of the above semiconductor device extends from a surface of the semiconductor layer to a surface of the insulating layer. An interface between the buffer region and the drift region is positioned equally in a vicinity of a bottom of the buffer region and in a vicinity of a surface of the buffer region, or shifted toward the body region in the vicinity of the bottom of the buffer region compared to that in the vicinity of the surface of the buffer region.

The vicinity of the surface of the buffer region corresponds to a vicinity of a surface excluding a segregation region at a surface of the buffer region. The vicinity of the bottom of the buffer region corresponds to a vicinity of a bottom excluding a segregation region at an interface between the buffer region and the insulating layer.

The buffer region of the semiconductor device is elongated toward the body region and semicircular at the elongated, longitudinal end in a plane view. Furthermore, in the semiconductor device, a radius of curvature of the semicircular portion in the vicinity of the bottom of the buffer region can be equal to or larger than a radius of curvature of the semicircular portion in the vicinity of the surface of the buffer region.

In a manufacturing method of a semiconductor device relating to the present invention, a step of forming the buffer region of the semiconductor device having the above structure has following steps. First, a resist film having an opening corresponding to the buffer region is formed on a surface of the semiconductor layer. Then, an impurity is ion-implanted in a vicinity of a surface of the semiconductor layer using the resist film. An impurity is ion-implanted also in a vicinity of a bottom of the semiconductor layer using the resist film to a concentration higher than a concentration of the impurity ion-implanted in the vicinity of the surface of the semiconductor layer.

A method of ion-implanting an impurity in a high impurity concentration region constituting the buffer region in the manner that the impurity concentration is higher in the vicinity of the bottom than in the vicinity of the surface of the semiconductor layer is not particularly restricted. For example, the impurity can be ion-implanted in the vicinity of the surface of the semiconductor layer and in the vicinity of the bottom of the semiconductor with different dose amounts or with different levels of acceleration energy. Alternatively, the impurity can be ion-implanted an increased/decreased number of times. After the impurity is ion-implanted in the semiconductor layer, the structure is subject to high temperature heat treatment to turn the region of the semiconductor layer into the buffer region.

In another manufacturing method of a semiconductor device relating to the present invention, a step of forming the buffer region has following steps. First, a first resist film having an opening corresponding to the buffer region is formed on a surface of the semiconductor layer, the opening being elongated toward the body region and semicircular at the elongated, longitudinal end in a plane view. An impurity is ion-implanted in a vicinity of a surface of the semiconductor layer using the first resist film. A second resist film having an opening is formed on the surface of the semiconductor layer, the opening encompassing the opening of the first resist film and having a longitudinal end shifted toward the body region compared to the longitudinal end of the opening of the first resist film. An impurity is ion-implanted in a vicinity of a bottom of the semiconductor layer using the second resist film.

A semiconductor device and a semiconductor device manufacturing method relating to the present invention can be applied to a high voltage horizontal MOSFET having a buffer region in an SOT substrate, a high voltage diode having a buffer region at a cathode region, and a MOS transistor having a super junction structure and having a buffer region at a drain region.

For example, when the semiconductor device relating to the present application is applied to a MOS transistor having a buffer region at a drain region, the structure will be as follows.

This semiconductor device is supposed to be a semiconductor device comprising an SOT substrate, a body region, a source region, a drift region, a drain region, a drain contact region and a gate electrode.

The SOI substrate has an insulating layer and a semiconductor layer of a first conductivity type provided on the insulating layer. The body region consisting of an impurity region of the first conductivity type is provided in the semiconductor layer. The source region consisting of an impurity region of a second conductivity type that is an opposite conductivity type to the first conductivity type is provided in a surface portion of the body region. The drift region consisting of a low concentration impurity region of the second conductivity type is provided in the semiconductor layer next to the body region.

The drain region consisting of a high concentration impurity region of the second conductivity type is provided in the semiconductor layer next to the drift region. The drain contact region is provided in a surface portion of the drain region. The gate electrode faces the body region and is provided on the semiconductor layer via a gate insulating film.

The drain region of the semiconductor device extends from a surface of the semiconductor layer to a surface of the insulating layer. An interface between the drain region and the drift region is positioned equally in a vicinity of a bottom of the drain region and in a vicinity of a surface of the drain region, or shifted toward the body region in the vicinity of the bottom of the drain region compared to that in the vicinity of the surface of the drain region.

The drain region of the semiconductor device is elongated toward the body region and semicircular at the elongated, longitudinal end in a plane view. Furthermore, in the semiconductor device, a radius of curvature of the semicircular portion in the vicinity of the bottom of the drain region can be equal to or larger than a radius of curvature of the semicircular portion in the vicinity of the surface of the drain region.

In a like manner, the above semiconductor device manufacturing method can be applied to a MOS transistor having a buffer region at a drain region as a semiconductor device. In this semiconductor device manufacturing method, a step of forming the drain region has following steps. First, a resist film having an opening corresponding to the drain region is formed on a surface of the semiconductor layer. Then, an impurity is ion-implanted in a vicinity of a surface of the semiconductor layer using the resist film. An impurity is ion-implanted also in a vicinity of a bottom of the semiconductor layer using the resist film to a concentration higher than a concentration of the impurity ion-implanted in the vicinity of the surface of the semiconductor layer.

Furthermore, the above other semiconductor device manufacturing method can be applied to a MOS transistor having a buffer region at a drain region as a semiconductor device. In this semiconductor device manufacturing method, a step of forming the drain region has following steps. First, a first resist film having an opening corresponding to the drain region is formed on a surface of the semiconductor layer, the opening being elongated toward the body region and semicircular at the elongated, longitudinal end in a plane view. An impurity is ion-implanted in a vicinity of a surface of the semiconductor layer using the first resist film. A second resist film having an opening is formed on the surface of the semiconductor layer, the opening encompassing the opening of the first resist film and having a longitudinal end shifted toward the body region compared to the longitudinal end of the opening of the first resist film. An impurity is ion-implanted in a vicinity of a bottom of the semiconductor layer using the second resist film.

In the present invention, the buffer region extends from a surface of the semiconductor layer to a surface of the insulating layer. An interface between the buffer region and the drift region is positioned equally in a vicinity of a bottom of the buffer region and in a vicinity of a surface of the buffer region, or shifted toward the body region in the vicinity of the bottom of the buffer region compared to that in the vicinity of the surface of the buffer region.

With the above structure, when an operation voltage in relation to the emitter electrode is applied to the collector electrode, a concentration of electric field in the vicinity of the bottom of the buffer region is moderated. Therefore, a collector-emitter breakdown voltage can further be increased. Consequently, a semiconductor device having a higher collector-emitter breakdown voltage in the OFF state wherein no voltage is applied between the gate and emitter electrodes can be realized.

Furthermore, in the present invention, the buffer region is elongated toward the body region and semicircular at the elongated, longitudinal end in a plane view. Furthermore, a radius of curvature of the semicircular portion in the vicinity of the bottom of the buffer region can be equal to or larger than a radius of curvature of the semicircular portion in the vicinity of the surface of the buffer region.

With the above structure, a concentration of electric field is moderated at an entire longitudinal end of the buffer region in the vicinity of the bottom of the buffer region when an operation voltage in relation to the emitter electrode is applied to the collector electrode. Therefore, a collector-emitter breakdown voltage can further be increased.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a cross-sectional view showing a semiconductor device in the first embodiment relating to the present invention. FIG. 1B is a graphical representation showing an N-type impurity concentration distribution along a line D-D in a buffer region of the semiconductor device shown in FIG. 1A.

FIGS. 2A and 2B are transversal cross-sectional views at lines E-E and F-F, respectively, of the buffer region of the semiconductor device shown in FIG. 1A. FIG. 2C is a graphical representation showing an electric field strength distribution along a transversal direction at depths of the lines E-E and F-F.

FIGS. 3A to 3D are step-by-step cross-sectional views showing a process of manufacturing a semiconductor device in the second embodiment relating to the present invention.

FIGS. 4A to 4D are step-by-step cross-sectional views showing a process of manufacturing a semiconductor device in the third embodiment relating to the present invention.

FIGS. 5A and 5C are cross-sectional views corresponding to FIGS. 4A and 4C, respectively. FIGS. 5B and 5D are plan views corresponding to FIGS. 5A and 5C, respectively.

FIG. 6 is a cross-sectional view showing a MOS type transistor having a buffer region at a drain region in an embodiment relating to the present invention.

FIG. 7A is a cross-sectional view showing a conventional high voltage horizontal IGBT. FIG. 7B is a graphical representation showing an N-type impurity concentration distribution along a line A-A in a buffer region of the high voltage horizontal IGBT shown in FIG. 7A.

FIGS. 8A and 8B are transversal cross-sectional views at lines B-B and C-C, respectively, of the buffer region of the high voltage horizontal IGBT shown in FIG. 7A. FIG. 8C is a graphical representation showing an electric field strength distribution along a transversal direction at depths of the lines B-B and C-C.

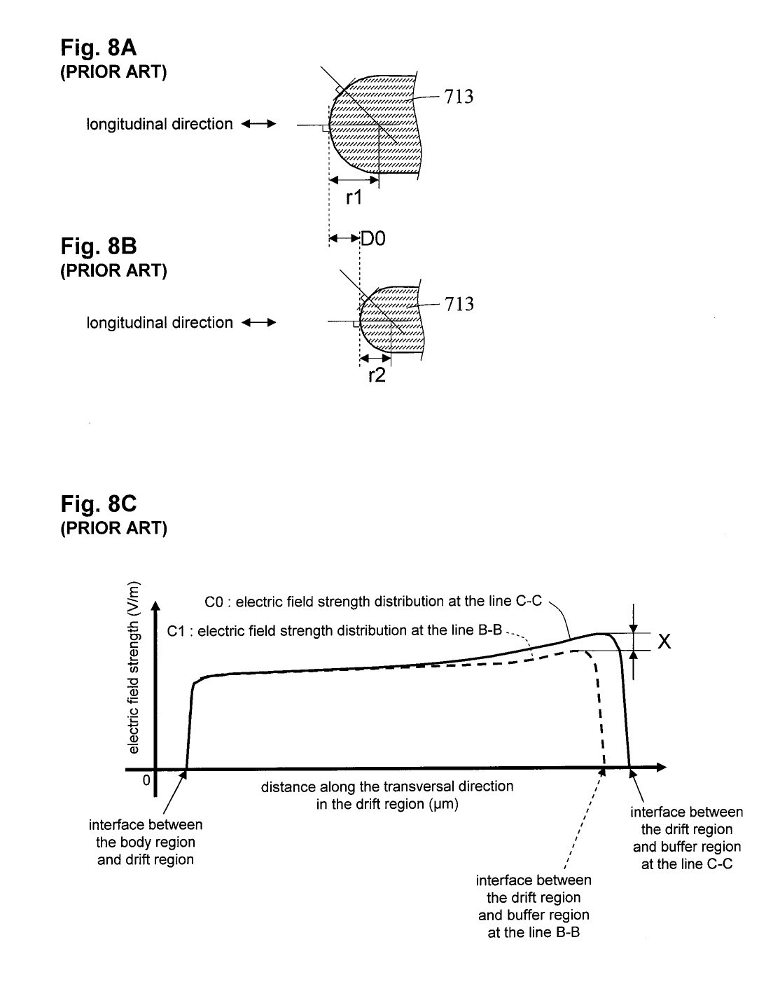

### DETAILED DESCRIPTION OF PREFERRED EMBODIMENTS

### First Embodiment

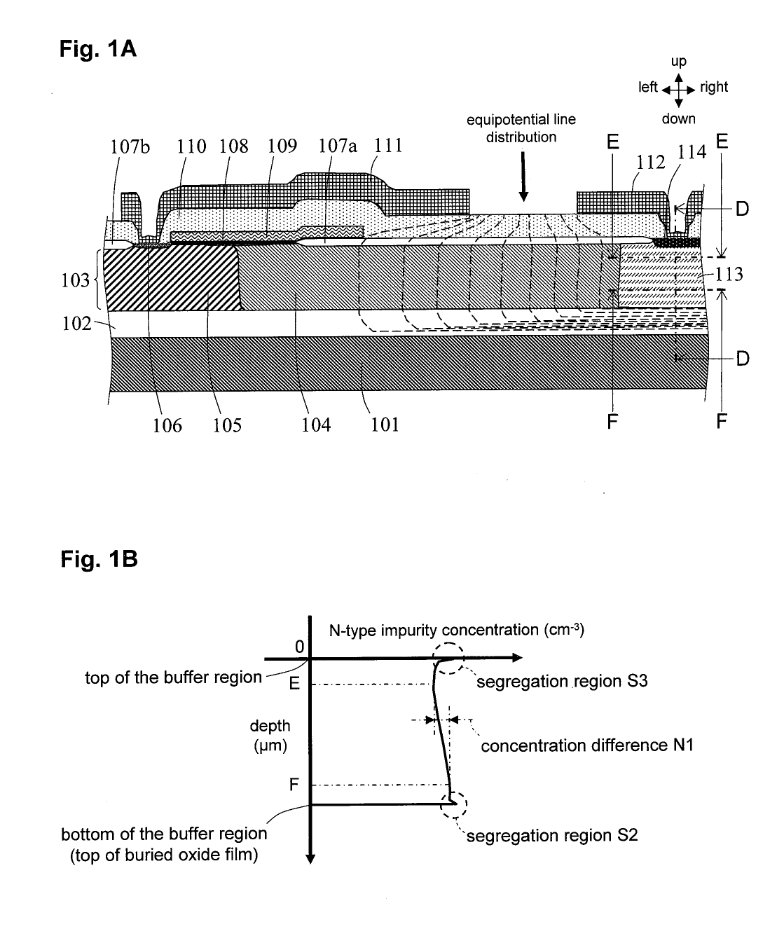

A semiconductor device in a first embodiment relating to the present invention is described in detail hereafter with reference to drawings. FIG. 1A is a cross-sectional view showing a structure of a high voltage horizontal IGBT which is the semiconductor device of this embodiment. The vertical direction in FIG. 1A corresponds to the vertical direction of the high voltage horizontal IGBT and the transversal direction in FIG. 1A corresponds to the transversal direction of the high voltage horizontal IGBT. FIG. 1A is a schematic illustration in which scales in the vertical and transversal directions are not equal.

As shown in FIG. 1A, a support substrate 101 is a base substrate on which the high voltage horizontal IGBT of this embodiment is formed. A buried oxide film 102 for a SOI substrate is formed on the support substrate 101. A P-type SOI layer 103 is formed on a top surface of the buried oxide film 102.

The support substrate 101 and the SOI layer 103 are separate silicon monocrystal layers. They are bonded together via the buried oxide film 102 having a thickness of approximately 1.0 to 3.0 μn to form a single SOI substrate.

The SOI layer 103 is mirror-polished and flattened to a thickness of approximately 2.0 to 4.0 μm from a surface of the SOI layer 103. The SOI layer 103 has a specific resistance of approximately 1 to 10 ω·cm.

An N-type impurity such as phosphorus or arsenic is ion-implanted in the SOI substrate, which is followed by a predetermined heat treatment to form a drift region 104 in the SOI layer 103. A dose amount of the N-type impurity is appropriately determined so that an average N-type impurity concentration in the drift region 104 of the completed IGBT is relatively low, for example 1×10¹⁶ to 1×10¹⁷ cm⁻³. For example, when the N-type impurity is phosphorus, the ion implantation condition includes a dose amount of approximately 1×10¹² to 1×10¹³ cm⁻² and an acceleration energy of approximately 250 keV to 2.0 MeV.

A buffer region 113 is formed in the SOI layer 103 next to the drift region 104. The buffer region 113 is elongated in the transversal direction and semicircular at the elongated, longitudinal end in a plane view.

In order to form the above buffer region 113, an N-type impurity is ion-implanted from the surface of the SOI layer 103 to a depth of approximately 2.0 to 4.0 μm in the manner that the N-type impurity concentration in the SOI layer 103 is higher in a vicinity of the surface of the buried oxide film 102 than in a vicinity of the surface of the SOI layer 103. Here, the surface of the buried oxide film 102 corresponds to the bottom of the buffer region 113 and the vicinity of the surface of the SOI layer 103 corresponds to the vicinity of the surface of the buffer region 113.

A method of ion-implanting the N-type impurity in the manner that the N-type impurity concentration is higher in the vicinity of the bottom of the buffer region 113 includes high acceleration ion implantation.

When high acceleration ion implantation is used, the N-type impurity is ion-implanted to the SOI layer 103 at the vicinity of the surface of the buried oxide film 102 with a predetermined N-type impurity dose amount and with an acceleration energy varied in a range, for example, from 1.5 to 4.0 MeV according to the thickness of the SOI layer 103. After the SOI layer 103 in which the N-type impurity is ion-implanted is subject to a predetermined heat treatment, the N-type impurity is thermal-diffused in the SOI layer 103 from the vicinity of the bottom to the vicinity of the surface. Consequently, the buffer region 113 extends from the surface of the SOI layer 103 to the surface of the buried oxide film 102.

Here, the predetermined N-type impurity dose amount is appropriately determined so that an average N-type impurity concentration in the buffer region 113 of the completed IGBT is approximately 5×10¹⁷ to 5×10¹⁸ cm⁻³. The N-type impurity concentration in the buffer region 113 is higher than that in the drift region 104.

FIG. 1B is a graphical representation showing an N-type impurity concentration distribution in the buffer region 113 along a line D-D shown in FIG. 1A. In the concentration distribution chart in FIG. 1B, a depth in the buffer region 113 along the line D-D from the surface to the bottom of the buffer region 113 is plotted as ordinate with an uppermost surface of the buffer region 113 being at the coordinates of zero and the N-type impurity concentration is plotted as abscissa. Here, the bottom of the region 113 corresponds to the surface of the buried oxide film 102.

As shown in FIG. 1B, it is understood that the N-type impurity concentration in the buffer region 113 is higher in the vicinity of the bottom than in the vicinity of the surface. For example, the N-type impurity concentration at a depth F corresponding to the vicinity of the bottom of the buffer region 113 is higher than that at a depth E corresponding to the vicinity of the surface of the buffer region 113, and there is a difference N1 in concentration between them. Here, for example, the depth E is approximately 0.2 to 0.7 μm below the surface of the buffer region 113 and the depth F is approximately 1.8 to 3.8 μm below the surface of the buffer region 113 provided that the SOI layer 103 has a thickness of approximately 2.0 to 4.0 μm from the surface.

In the high voltage horizontal IGBT of this embodiment, as shown in FIG. 1B, it is understood that the N-type impurity concentration in the buffer region 113 is increased with depth in the depth direction from the vicinity of the surface to the vicinity of the bottom.

As shown in a region S2 in FIG. 1B, segregation occurs in the vicinity of an interface between the buffer region 113 and the buried oxide film 102. Furthermore, as shown in a region S3 in FIG. 1B, similar segregation occurs at the uppermost surface of the buffer region 113. However, as described above, segregation has minor influence on the concentration distribution compared to thermal diffusion. Therefore, it can be said that the N-type impurity concentration distribution in the buffer region 113 is such that the N-type impurity concentration is increased with depth in the depth direction from the vicinity of the surface to the vicinity of the bottom.

The high N-type impurity concentration in the buffer region 113 in the depth direction from the top surface can be measured using a secondary ion mass spectrometer (SIMS), focused ion beam (FIB), scanning capacitance microscope (SCM), scanning spread resistance microscopy (SSRM) and the like.

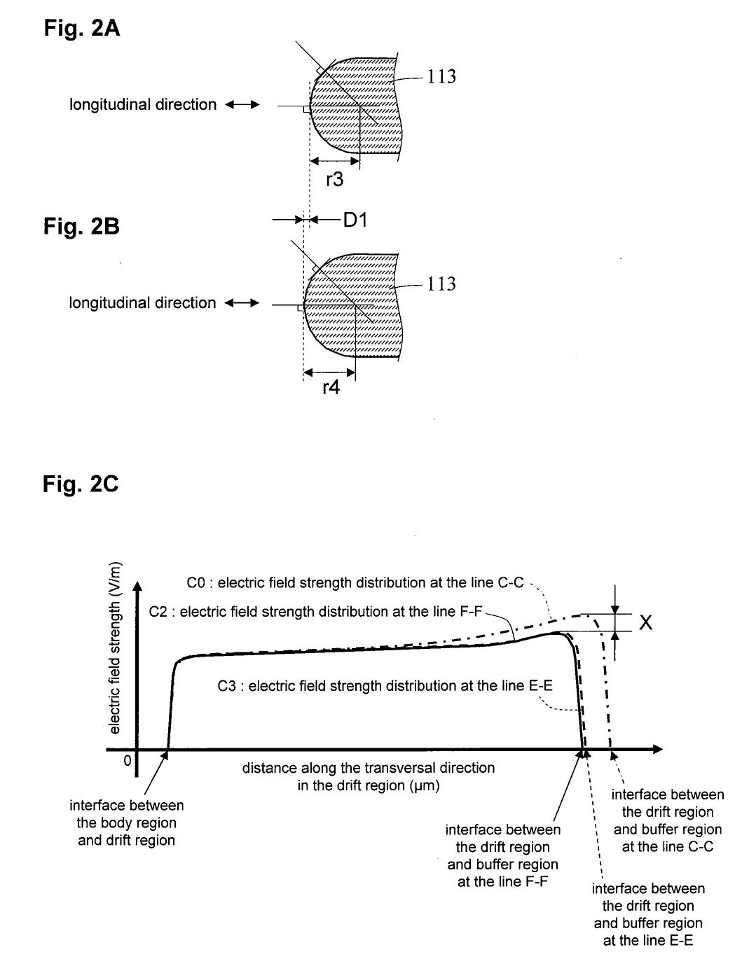

FIG. 2A is a transversal cross-sectional view of the buffer region 113 at a line E-E shown in FIG. 1A (corresponding to a position E in FIG. 1B). FIG. 2B is a transversal cross-sectional view of the buffer region 113 at a line F-F shown in FIG. 1A (corresponding to a position F in FIG. 1B).

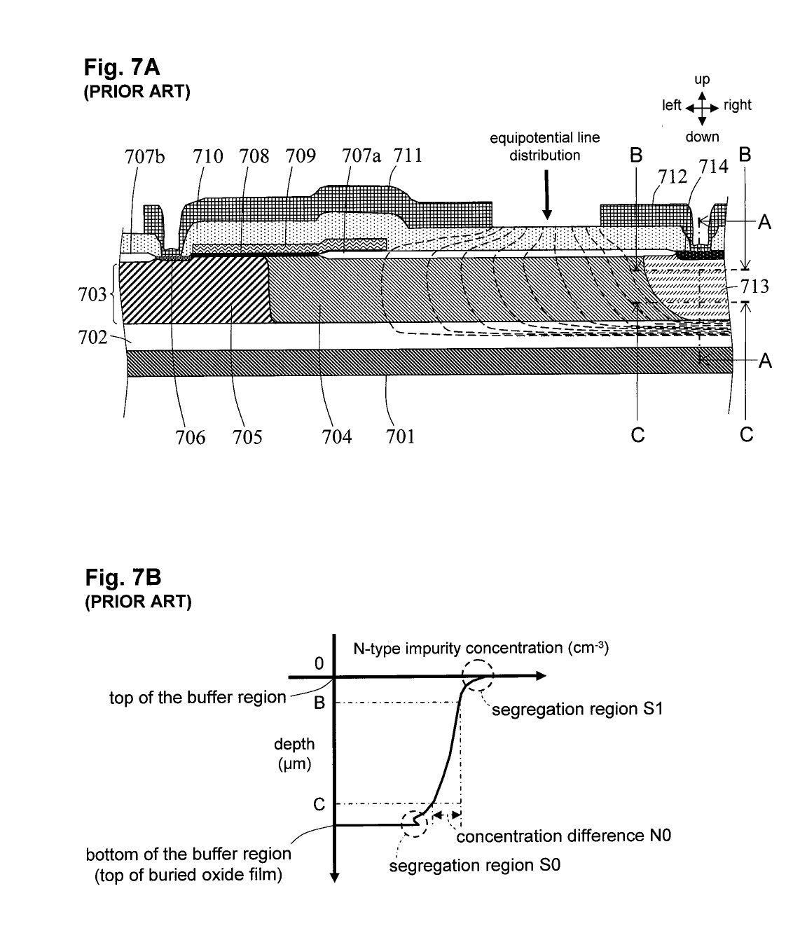

The transversal direction in FIGS. 2A and 2B corresponds to the longitudinal direction of the buffer region 113. Furthermore, the body region 105, which is described later, is located a left side in FIGS. 2A and 2B. The longitudinal end of the buffer region 113 corresponds to the interface between the buffer region 113 and the drift region 104. For easy comparison of a structure between the buffer region 113 of a high voltage horizontal IGBT of this embodiment and the buffer region 713 of a conventional high voltage horizontal IGBT, the depth in the buffer region 113 at the line E-E shown in FIG. 1A is equal to the depth in the buffer region 713 at the line B-B shown in FIG. 7A. Similarly, the depth in the buffer region 113 at the line F-F shown in FIG. 1A is equal to the depth in the buffer region 713 at the line C-C shown in FIG. 7A.

As shown in FIGS. 2A and 2B, the buffer region 113 is elongated toward the body region 105 in a plane view. The longitudinal end of the buffer region 113 is semicircular in the plane view. Furthermore, it is understood that the radius of curvature (r4) of the semicircular portion of the buffer region 113 at the line F-F is larger than the radius of curvature (r3) of the semicircular portion of the buffer region 113 at the line E-E. This corresponds to the structure that the N-type impurity concentration in the buffer region 113 is higher at the depth F corresponding to the vicinity of the bottom than at the depth E corresponding to the vicinity of the surface.

The longitudinal end of the buffer region 113 corresponds to the interface between the buffer region 113 and the drift region 104. The body region 105 is located at the longitudinally opposite position to the buffer region 113. Therefore, the interface between the buffer region 113 and the drift region 104 is shifted toward the body region 105 in the vicinity of the bottom of the buffer region 113 compared to that in the vicinity of the surface of the buffer region 113.

The radius of curvature (r4) of the semicircular portion of the buffer region 113 at the line F-F is larger than the radius of curvature (r3) of the semicircular portion of the buffer region 113 at the line E-E. In other words, the longitudinal end of the buffer region 113 at the vicinity of the bottom of the buffer region 113 entirely protrudes toward the body region 105 compared to the longitudinal end of the buffer region 113 at the vicinity of the surface of the buffer region 113.

More specifically, as shown in FIGS. 2A and 2B, it is understood that the longitudinal end of the buffer region 113 at the line F-F protrudes toward the body region 105 by a predetermined longitudinal distance D1 compared to the longitudinal end of the buffer region 113 at the line E-E.

Consequently, the buffer region 113 of the high voltage horizontal IGBT of this embodiment has a completely different structure from the buffer region 713 of the conventional high voltage horizontal IGBT.

The N-type impurity concentration defining the interface between the buffer region 113 and the drift region 104 can be any predetermined concentration as long as it is between the high N-type impurity concentration in the buffer region 113 and the low N-type impurity concentration in the drift region 104. For example, a concentration of approximately 1×10¹⁷ cm⁻³ is utilized in embodiments relating to the present invention.

A P-type impurity such as boron is ion-implanted in a relatively high concentration to form a collector region 114 in a surface portion of the buffer region 113. A dose amount of the P-type impurity is appropriately determined so that an average P-type impurity concentration in the collector region 114 of the completed IGBT is relatively high, for example, 1×10¹⁹ to 1×10²⁰ cm⁻³. For example, when the P-type impurity is boron, the ion implantation condition includes a dose amount of approximately 1×10¹⁵ to 1×10¹⁶ cm⁻² and an acceleration energy of approximately 20 to 80 keV.

Furthermore, the body region 105 of a P-type impurity is formed in the SOI layer 103 at the opposite position to the buffer region 113 in relation to the drift region 104. A dose amount of the P-type impurity is appropriately determined so that an average P-type impurity concentration in the body region 105 of the completed IGBT is, for example, 1×10¹⁶ to 1×10¹⁷ cm⁻³. For example, when the P-type impurity is boron, the ion implantation condition includes a dose amount of approximately 1×10¹² to 1×10¹³ cm⁻³ and an acceleration energy of approximately 20 to 100 keV.

Furthermore, an N-type impurity such as phosphorus is ion-implanted in a relatively high concentration to form an emitter region 106 in a surface portion of the body region 105. A dose amount of the N-type impurity is appropriately determined so that an average P-type impurity concentration in the emitter region 106 of the completed IGBT is relatively high, for example, 1×10¹⁹ to 1×10²⁰ cm⁻³. For example, when the N-type impurity is phosphorus, the ion implantation condition includes a dose amount of approximately 1×10¹⁵ to 1×10¹⁶ cm⁻² and an acceleration energy of approximately 20 to 80 keV.

Furthermore, a first LOCOS oxide film 107a is formed by thermal oxidation to cover a part of the surface of the drift region 104, the surface of the buffer region 113 and a part of the surface of the collector region 114. The formed first LOCOS oxide film 107a is an insulating film and has a thickness of approximately 400 to 700 nm. Furthermore, a second LOCOS oxide film 107b is formed to cover a part of the surface of the body region 105. The second LOCOS oxide film 107b is in contact with the emitter region 106 formed on the surface of the body region 105.

A gate oxide film 108 is formed between the first LOCOS oxide film 107a and the emitter region 106 to cover a part of the surface of the drift region 104 and a part of the surface of the body region 105. The gate oxide film 108 is an insulating film formed by thermal oxidation to a thickness of approximately 10 to 30 nm and in contact with the first LOCOS oxide film 107a.

A gate electrode 109 consisting of an N-type polysilicon film is formed on a surface of the gate oxide film 108. The gate electrode 109 faces the body region 105 and the drift region 104 and is insulated from the SOI layer 103 by the gate oxide film 108. Furthermore, an interlayer insulating film 110 is formed to cover a surface of the gate electrode 109, a surface of the first LOCOS oxide film 107a and a part of a surface of the collector region 114.

An emitter electrode 111 is formed on a surface of the interlayer insulating film 110 on a side to the emitter region 106. The emitter electrode 111 consists of a metal electrode and is electrically connected to a surface of the emitter region 106. Furthermore, a collector electrode 112 is formed on a surface of the interlayer insulating film 110 at an opposite position to the emitter electrode 111 or on a side to the collector region 114. The collector electrode 112 consists of a metal electrode and is electrically connected to a surface of the collector region 114. The collector electrode 112 and the emitter electrode 111 are electrically separated.

In the above high voltage horizontal IGBT, when a high positive voltage in relation to the emitter electrode 111 (for example 150 to 250 V) is applied to the collector electrode 112, it is difficult for any potential difference to occur in the buffer region 113 while a potential difference occurs in the drift region 104 because there is a significant difference in the N-type impurity concentration between the buffer region 113 and the drift region 104 of the high voltage horizontal IGBT. Since the potential is uniform in the buffer region 113, multiple equipotential lines occurring in the drift region 104 in the transversal direction follow a contour of the interface between the drift region 104 and the buffer region 113 in the vertical cross-sectional view of the drift region 104.

As described above, the N-type impurity concentration in the buffer region 113 in the depth direction is higher in the vicinity of the bottom than in the vicinity of the surface. Therefore, the interface defined by a specific N-type impurity concentration protrudes more towards the drift region 104 with depth in the buffer region 113 in a vertical cross-sectional view of the buffer region 113.

FIG. 1A shows an equipotential line distribution when no positive voltage in relation to the emitter electrode 111 is applied to the gate electrode 9, or in the OFF state, and a positive voltage in relation to the emitter electrode 111 is applied to the collector electrode 112.

As shown in FIG. 1A, multiple equipotential lines follow the same contour as the interface between the buffer region 113 and the drift region 104 and occur in the drift region 104 in the transversal direction. The interface protrudes somewhat towards the body region 105 with depth in the buffer region 113. The protrusion corresponds to the predetermined distance D1 shown in FIGS. 2A and 2B. The predetermined distance D1 is very small; therefore, it can be said that the interface is nearly parallel along the depth direction of the buffer region 113.

FIG. 2C shows an electric field strength distribution along the transversal direction at the depths of the lines E-E and F-F shown in FIG. 1A. FIG. 2C also shows the electric field strength distribution along the transversal direction at the depth of the line C-C shown in FIG. 7C for reference.

As described above, the equipotential lines in the drift region 104 are nearly parallel in the depth direction of the buffer region 113; the multiple equipotential lines do not come closer to each other in the vicinity of the bottom of the buffer region 113. Therefore, as shown in FIG. 2C, it is understood that in the vicinity of the interface between the buffer region 113 and the drift region 104, the electric field strength in the vicinity of the bottom of the buffer region 113 (corresponding to a curve C2 in FIG. 2C) is equal to that in the vicinity of the surface of the buffer region 113 (corresponding to a curve C3 in FIG. 2C).

More specifically, as shown in FIG. 2C, in the vicinity of the interface between the buffer region 113 and the drift region 104, the electric field strength in the vicinity of the bottom of the buffer region 113 (the curve C2 in FIG. 2C) is somewhat lower than that in the vicinity of the surface of the buffer region 113 (the curve C3 in FIG. 2C) in accordance with the equipotential lines protruding towards the body region 105.

On the other hand, the electric field strength in the vicinity of the interface between the buffer region 113 and the drift region 104 is lower at the depth of the line F-F than at the depth of the line C-C (the curve C0) shown in FIG. 2C by a specific electric field strength difference X. Consequently, the high voltage horizontal IGBT of this embodiment can moderate the concentration of electric field in the vicinity of the bottom of the buffer region 713 in the conventional high voltage horizontal IGBT and reduce it by the electric field strength difference X, allowing for a higher collector-emitter breakdown voltage.

As described above, the buffer region of this embodiment extends from the surface of the SOI layer to the surface of the buried oxide film and the interface between the buffer region and the drift region protrudes towards the body region in the vicinity of the bottom of the buffer region compared to that in the vicinity of the surface of the buffer region.

With the above structure, when a positive voltage in relation to the emitter electrode is applied to the collector electrode, the concentration of electric field in the vicinity of the bottom of the buffer is moderated, allowing for a higher collector-emitter breakdown voltage. Consequently, a high voltage horizontal IGBT or MOSFET having a higher collector-emitter breakdown voltage in the OFF state wherein no voltage is applied between the gate electrode and the emitter electrode can be realized.

Furthermore, the buffer region is elongated towards the body region and semicircular at the elongated, longitudinal end in a plane view. The radius of curvature of the semicircular portion can be larger in the vicinity of the bottom of the buffer region than in the vicinity of the surface of the buffer region.

With this structure, the concentration of electric field is moderated at an entire longitudinal end of the buffer region in the vicinity of the bottom of the buffer region when a positive voltage in relation to the emitter electrode is applied to the collector electrode. Therefore, the collector-emitter breakdown voltage can further be increased.

Even if the interface between the buffer region and the drift region is positioned equally in the vicinity of the bottom of the buffer region and in the vicinity of the surface of the buffer region, the efficacy of the present invention can be obtained as a result of the above described effect.

Furthermore, even if the radius of curvature of the semicircular portion in the vicinity of the bottom of the buffer region is equal to the radius of curvature of the semicircular portion in the vicinity of the surface of the buffer region, the efficacy of the present invention can be obtained as a result of the above described effect.

The radius of curvature of the semicircular portion can be calculated by any method including a method below.

The high voltage horizontal IGBT for which the radius curvature is calculated is mirror-polished until the vicinity of the surface of the buffer region 113 of the high voltage horizontal IGBT is exposed in a plane view. The high N-type impurity concentration region and the low N-type impurity concentration region are identified by SCM or SSRM. A specific concentration between the concentrations in the high and low concentration regions is defined as the concentration at the interface between the buffer region 113 and the drift region 104 and the interface between the buffer region 113 and the drift region 104 is identified. Multiple points belonging to the longitudinal end of the buffer region 113 are identified by specifying the interface between the buffer region 113 and the drift region 104 at multiple positions on the plane of the high voltage horizontal IGBT. Normal lines are drawn at two points on the longitudinal end constructed by the identified multiple points. The intersection of the two normal lines is assumed to be a center of the semicircular portion at the longitudinal end. The radius of curvature of the semicircular portion is calculated from distances between this center and the two points. Here, the normal line means a line perpendicular to a tangent line at a specific point on the semicircular portion. Furthermore, the mirror-polished surface of the buffer region 113 of the high voltage horizontal IGBT is mirror-polished to the extent that the surface of the buried oxide film 102 of the high voltage horizontal IGBT is not exposed in a plane view, in other words up to the vicinity of the bottom of the buffer region 113 of the high voltage horizontal IGBT. After the mirror-polishing, the radius of curvature of the semicircular portion at the longitudinal end in the vicinity of the bottom of the buffer region 113 is calculated in the above described procedure. The radius of curvature can be calculated, for example, by image analysis on the identified interface between the buffer region 113 and the drift region 104 using a specific arithmetic program.

### Second Embodiment

A manufacturing method of a semiconductor device according to the present invention is described hereafter with reference to drawings.

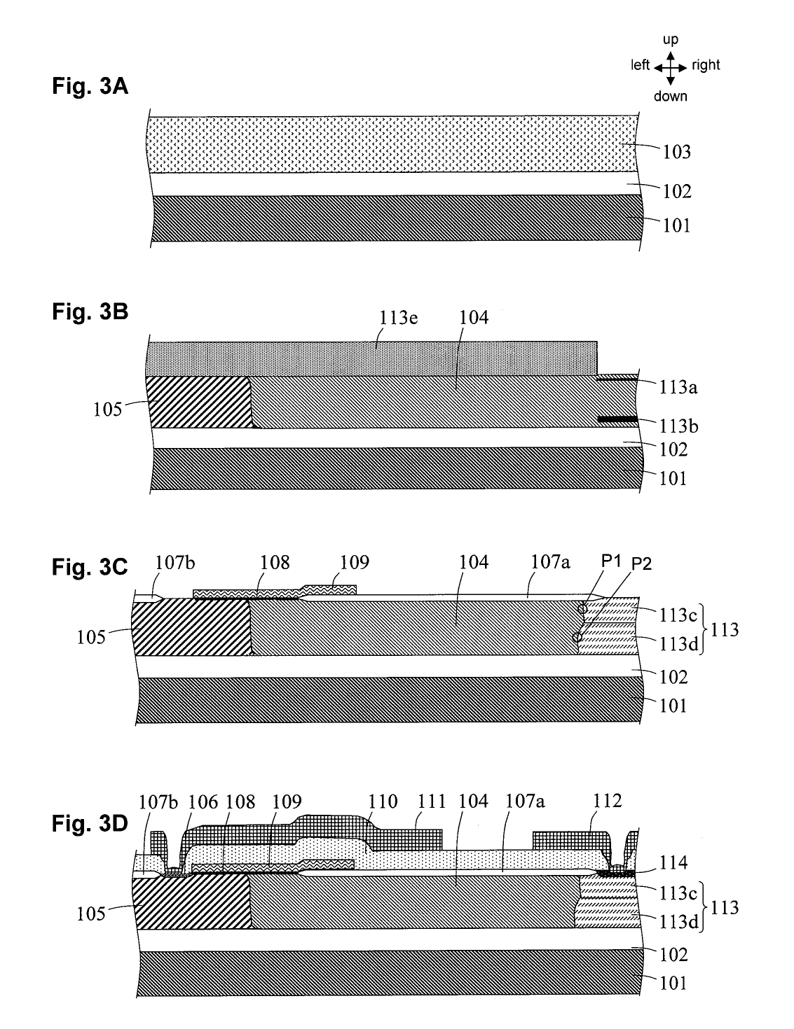

FIGS. 3A to 3D are step-by-step cross-sectional views showing a process of manufacturing a semiconductor device relating to the present invention. FIGS. 3A to 3D are schematic illustrations in which scales in the vertical and transversal directions are not equal.

First, as shown in FIG. 3A, a buried oxide film 102 is formed on a support substrate 101 which is a base substrate for forming a high voltage horizontal IGBT. Then, a P-type SOI layer 103 is formed on the buried oxide film 102. The support substrate 101 and the SOI layer 103 are separate silicon monocrystal layers. They are bonded together via the buried oxide film 102 having a thickness of approximately 1.0 to 3.0 μm to form an SOI substrate. The SOI layer 103 is mirror-polished and flattened to a thickness of approximately 2.0 to 4.0 μm from the surface of the SOI layer 103. The SOI substrate can be formed by SIMOX process instead of bonded process.

Then, as shown in FIG. 3B, an N-type impurity such as phosphorus is ion-implanted in a corresponding region of the SOI layer 103 to a drift region 104 for example with a low dose amount of approximately 1×10¹² to 1×10¹³ cm⁻² and with acceleration energy of approximately 250 keV to 2.0 MeV. Furthermore, a P-type impurity such as boron is ion-implanted in a corresponding region of the SOI layer 103 to a body region 105 for example at a low dose amount of approximately 1×10¹² to 1×10¹³ cm⁻² and an acceleration energy of approximately 20 to 100 keV. After the N-type and P-type impurities are ion-implanted, the structure is subject to high temperature heat treatment approximately at 1000° C. to 1250° C. for a predetermined period of time to form the drift region 104 and the body region 105. The predetermined period of time may be changed as appropriate according to a specification of the semiconductor device.

The drift region 104 formed with the aforementioned dose amount and acceleration energy has an average N-type impurity concentration of approximately 1×10¹⁶ to 1×10¹⁷ cm⁻³ and the body region 105 has an average P-type impurity concentration of approximately 1×10¹⁶ to 1×10¹⁷ cm⁻³.

Then, a resist film 113e having a thickness of approximately 1 to 5 μm and an opening at a position corresponding to a buffer region 113 is formed on a surface of the body region 105 and a part of a surface of the drift region 104. An N-type impurity such as phosphorus is ion-implanted in a vicinity of the surface of the SOI layer 103 for example with a dose amount of approximately 2×10¹³ to 5×10¹⁴ cm⁻² and with an acceleration energy of approximately 40 to 200 keV (“low acceleration energy” hereafter) using the resist film 113e as a mask to form a first injection layer 113a.

In accordance with the buffer region 113 to be formed, the opening of the resist film 113e is elongated toward the body region 105 in the transversal direction in FIG. 3B and is semicircular at the elongated, longitudinal end in a plane view.

Next, an N-type impurity is ion-implanted to the SOI layer 103 at the vicinity of the surface of the buried oxide film 102 rather than in the vicinity of the surface of the SOI layer 103 with a predetermined range of dose amount (2×10¹³ to 5×10¹⁴ cm⁻²) by high acceleration ion implantation to form a second injection layer 113b. The N-type impurity acceleration energy is changed as appropriate in a range approximately from 1.5 to 4 MeV (“high acceleration energy” hereafter) according to a thickness of the SOI layer 103. When the N-type impurity is ion-implanted with the high acceleration energy, it is preferable to use a dose amount larger than that of ion-implantation with the low acceleration energy.

Subsequently, as shown in FIG. 3C, the structure is subject to high temperature heat treatment approximately at 1000° C. to 1250° C. for a predetermined period of time. This allows the N-type impurity in the first injection layer 113a and the second injection layer 113b to thermal-diffuse so as to form a first buffer region 113c and a second buffer region 113d. The first buffer region 113c and the second buffer region 113d overlap one another, and they form a single buffer region 113. This high temperature heat treatment can also serve as the high temperature heat treatment for forming the drift region 104 and the body region 105. The predetermined period of time is changed as appropriate according to a specification of the semiconductor device.

The aforementioned high temperature heat treatment also results in forming segregation regions where the N-type impurity accumulates at an interface between the buried oxide film 102 and the second buffer region 113d and at an uppermost surface of the first buffer region 113c. However, in the above described manufacturing method, the segregation has minor influence on a concentration distribution compared to the thermal diffusion. The N-type impurity concentration distribution in the single buffer region 113 is such that the N-type impurity concentration is higher in the vicinity of the bottom of the buffer region 113 than in the vicinity of the surface of the buffer region 113. Furthermore, as shown in FIG. 3C, the single buffer region 113 extends from the surface of the SOI layer 103 to the surface of the buried oxide film 102. The interface between the buffer region 113 and the drift region 104 is shifted toward the body region 105 in the vicinity of the bottom of the buffer region 113 compared to that in the vicinity of the surface of the buffer region 113.

In FIG. 3B, two different levels of N-type impurity acceleration energy are set and the N-type impurity is implanted once at each level in order to form a single buffer region 113. The N-type impurity can be implanted two or more times according to predetermined acceleration energy levels.

If the N-type impurity cannot be ion-implanted at the high acceleration energy because of limited ion implantation apparatus, the following method can be utilized.

Within the range of the low acceleration energy, for example, the minimum acceleration energy is defined as the acceleration energy for ion-implanting the N-type impurity in the vicinity of the surface of the SOI layer 103 (the vicinity-of-the surface acceleration energy). On the other hand, the maximum acceleration energy is defined as the acceleration energy for ion-implanting the N-type impurity in the vicinity of the bottom of the SOI layer 103 (the vicinity-of-the bottom acceleration energy). In other words, the depth in the SOI layer 103 to which the N-type impurity is ion-implanted is changed by increasing a difference between the vicinity-of-the surface acceleration energy and the vicinity-of-the bottom acceleration energy within the range of the low acceleration energy. In addition to such the change of the ion-implanted depth, a number of times the N-type impurity is implanted at each acceleration energy level is changed so that the N-type impurity concentration distribution in the buffer region 113 is such that the N-type impurity concentration is higher in the vicinity of the bottom of the buffer region 113 than in the vicinity of the surface of the buffer region 113. The ion implantation can be performed multiple times at the vicinity-of-the surface acceleration energy and multiple times at the vicinity-of-the bottom acceleration energy.

In the above case, two levels, minimum and maximum, of acceleration energy are so set as to maximize the difference between them. It is unnecessary to utilize the minimum and maximum acceleration energy levels within the range of the low acceleration energy, as long as such an N-type impurity concentration distribution in the buffer region 113 that the N-type impurity concentration is higher in the vicinity of the bottom of the buffer region 113 than in the vicinity of the surface of the buffer region 113 is obtained.

After the ion implantation, the structure is subject to high temperature heat treatment for example approximately at 1000° C. to 1250° C. for a longer period of time than the aforementioned predetermined period of time, whereby the N-type concentration distribution in the buffer region 113 extends from the surface of the SOI layer 103 to the surface of the buried oxide film 102. Furthermore, the interface between the buffer region 113 and the drift region 104 is shifted toward the body region 105 in the vicinity of the bottom of the buffer region 113 compared to that in the vicinity of the surface of the buffer region 113.

The longitudinal end of the buffer region 113 is semicircular because of the resist film 113e. Furthermore, the high temperature heat treatment causes the N-type impurity to thermal-diffuse from a higher concentration area to a lower concentration area uniformly in the vertical and transversal directions. Therefore, if the buffer region 113 has the aforementioned N-type impurity concentration distribution in the depth direction, the radius of curvature of the semicircular portion in the vicinity of the bottom of the buffer region 113 is equal to or larger than the radius of curvature of the semicircular portion in the vicinity of the surface of the buffer region 113.

In FIG. 3C, there are two interface peaks protruding toward the body region 105 in the vicinity of the interface between the buffer region 113 and the drift region 104; one in the vicinity of the surface of the first buffer region 113c and the other in the vicinity of the bottom of the second buffer region 113d. An interface peak P2 in the vicinity of the bottom of the second buffer region 113d protrudes more towards the body region 105 than an interface peak P1 in the vicinity of the surface of the first buffer region 113c. Here, in FIG. 3C, the interface peak P1 in the vicinity of the surface of the first buffer region 113c is a gentle peak and the interface peak P2 in the vicinity of the bottom of the second buffer region 113d is a sharp peak.

In this structure, the N-type impurity concentration in the buffer region 113 is the lowest in a middle part. The middle part of the buffer region 113 corresponds to a contact portion between the first buffer region 113c and the second buffer region 113d.

Then, a first LOCOS oxide film 107a is formed on the surface of the SOI layer 103 to a thickness of approximately 400 to 700 nm by thermal oxidation to cover a part of the surface of the drift region 104 and a part of the surface of the buffer region 113. Furthermore, a second LOCOS oxide film 107b is formed to cover a part of the surface of the body region 105.

Then, a gate oxide film 108 is formed to a thickness of approximately 10 to 30 nm by thermal oxidation to cover a part of the surface of the first LOCOS oxide film 107a, the surface of the drift region 104 and a part of the surface of the body region 105. An N-type polysilicon film is deposited on a surface of the gate oxide film 108 and selectively etched to form a gate electrode 109.

Then, as shown in FIG. 3D, a P-type impurity such as boron is ion-implanted in a relatively high concentration to form a collector region 114 in a surface portion of the buffer region 113. A dose amount of the P-type impurity is appropriately determined so that an average P-type impurity concentration in the collector region 114 of the completed IGBT is relatively high, for example 1×10¹⁹ to 1×10²⁰ cm⁻³. For example, when the P-type impurity is boron, the ion implantation condition includes a dose amount of approximately 1×10¹⁵ to 1×10¹⁶ cm⁻² and an acceleration energy of approximately 20 to 80 keV.

Furthermore, an N-type impurity such as phosphorus is ion-implanted in a relatively high concentration to form an emitter region 106 in a surface portion of the body region 105. A dose amount of the N-type impurity is appropriately determined so that an average N-type impurity concentration in the emitter region 106 of the completed IGBT is relatively high, for example 1×10¹⁹ to 1×10²⁰ cm⁻³. For example, when the N-type impurity is phosphorus, the ion implantation condition includes a dose amount of approximately 1×10¹⁵ to 1×10¹⁶ cm⁻² and an acceleration energy of approximately 20 to 80 keV.

Subsequently, an interlayer insulating film 110 is formed on the top surface of the SOI layer 103 to cover an entire surface of the gate electrode 109, first LOCOS oxide film 107a and the like.

Then, an opening is formed in the interlayer insulating film 110 at a position corresponding to the emitter region 106, and an emitter electrode 111 for example consisting of Al alloy is formed. Then, an opening is formed in the interlayer insulating film 110 at a position corresponding to the collector region 114, and a collector electrode 112 for example consisting of Al alloy is formed. The emitter electrode 111 and collector electrode 112 are electrically connected to the emitter region 106 and the collector region 114, respectively, via the respective openings.

In this way, the high voltage horizontal IGBT in an embodiment relating to the present invention is completed.

As described above, in the manufacturing method of the high voltage horizontal IGBT in this embodiment, a process of forming the buffer region starts with forming a resist film having an opening corresponding to the buffer region on the surface of the SOI layer. Then, using the resist film, an impurity is ion-implanted in the vicinity of surface of the SOI layer, and an impurity is ion-implanted in the vicinity of the bottom of the SOI layer with a concentration higher than that in the vicinity of the surface of the SOI layer.

Consequently, the buffer region of the obtained high voltage horizontal IGBT extends from the surface of the SOI layer to the surface of the buried oxide film. Furthermore, in the high voltage horizontal IGBT, the interface between the buffer region and the drift region is equally positioned in the vicinity of the bottom of the buffer region and in the vicinity of the surface of the buffer region, or shifted toward the body region in the vicinity of the bottom of the buffer region compared to that in the vicinity of the surface of the buffer region. Therefore, as explained in the first embodiment, the concentration of electric field in the vicinity of the bottom of the buffer region is moderated when a positive voltage in relation to the emitter electrode is applied to the collector electrode, allowing for a higher collector-emitter breakdown voltage.

Furthermore, the buffer region of the high voltage horizontal IGBT is elongated toward the body region and semicircular at the elongated, longitudinal end in a plane view. Furthermore, in the high voltage horizontal IGBT, the radius of curvature of the semicircular portion in the vicinity of the bottom of the buffer region is equal to or larger than the radius of curvature of the semicircular portion in the vicinity of the surface of the buffer region. Therefore, the efficacy described in regard to the first embodiment is obtained.

The manufacturing method described in the second embodiment is an excellent manufacturing method because a high voltage horizontal IGBT according to an embodiment relating to the present invention can easily be produced by appropriately changing the N-type impurity dose amount, acceleration energy and number of implantation operations so as to appropriately adjust the ion-implanted N-type impurity amount even if the SOI substrate has an SOI layer 103 of a variant or large thickness.

### Third Embodiment

A manufacturing method of a semiconductor device according to the present invention is described hereafter with reference to drawings.

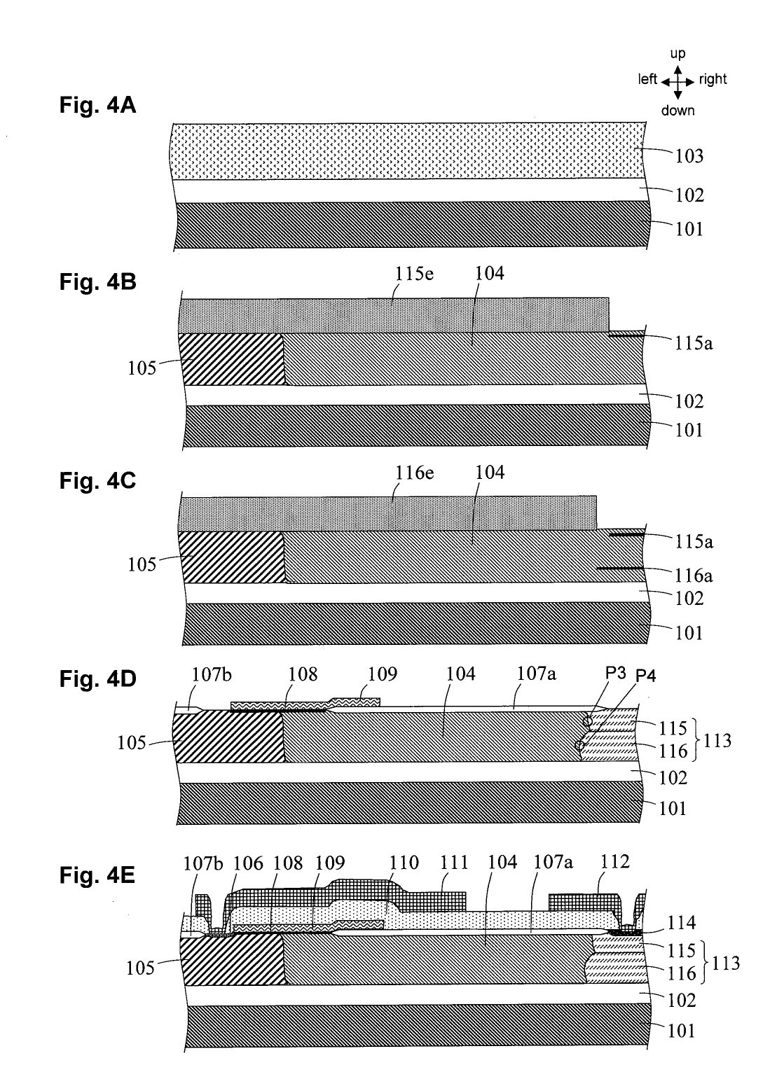

FIGS. 4A to 4D are step-by-step cross-sectional views showing a process of manufacturing a semiconductor device relating to this embodiment. FIGS. 4A to 4E are schematic illustrations in which scales in the vertical and transversal directions are not equal.

The third embodiment is different from the second embodiment in that resist films having different openings are used in ion implantation to form a buffer region. The rest is the same as in the second embodiment.

In the following explanation, the buffer region formed by ion-implanting an impurity in a vicinity of the surface of a semiconductor layer is defined a third buffer region and the buffer region formed by ion-implanting an impurity in a vicinity of the bottom of the semiconductor layer is defined a fourth buffer region.

First, as shown in FIG. 4A, a support substrate 101 on which a buried oxide film 102 and a P-type SOI layer 103 are formed is prepared in order to form a high voltage horizontal IGBT. This support substrate 101 is the same as the support substrate 101 in the second embodiment shown in FIG. 3A and its explanation is omitted.

Then, as shown in FIG. 4B, a drift region 104 and a body region 105 are formed. The drift region 104 and the body region 105 are formed in the same manner as in the second embodiment shown in FIG. 3B.

Then, a first resist film 115e having a thickness of approximately 1 to 3 μm and an opening at a position corresponding to a third buffer region 115 is formed on the surface of the body region 105 and a part of the surface of the drift region 104. An N-type impurity is ion-implanted in a surface portion of the SOI layer 103, for example, with a dose amount of approximately 2×10¹³ to 5×10¹⁴ cm⁻² and with an acceleration energy of approximately 40 to 200 keV (“low acceleration energy” hereafter) using the first resist film 115e as a mask to form a third injection layer 115a.

Then, as shown in FIG. 4C, the first resist film 115e is removed after the third injection layer 115a is formed. Then, after the first resist film 115e is removed, a second resist film 116e having a thickness of approximately 1 to 5 μm and an opening at a position corresponding to a fourth buffer region 116 is formed on the surface of the body region 105 and a part of the surface of the drift region 104.

After the second resist film 116e is formed, an N-type impurity is ion-implanted in the SOI layer 103 in the vicinity of the surface of the buried oxide film 102 by high acceleration ion implantation at a predetermined range of dose amount (2×10¹³ to 5×10¹⁴ cm⁻²) using the second resist film 116e as a mask to form a fourth injection layer 116a. The N-type impurity acceleration energy is changed as appropriate, for example, within a range from 1.5 to 4 MeV according to the thickness of the SOI layer 103. When the N-type impurity is ion-implanted at the high acceleration energy, it is preferable to use a higher dose amount than that of the ion-implantation with the low acceleration energy.

The aforementioned openings of the first resist film 115e and the second resist film 116e is described in detail hereafter.

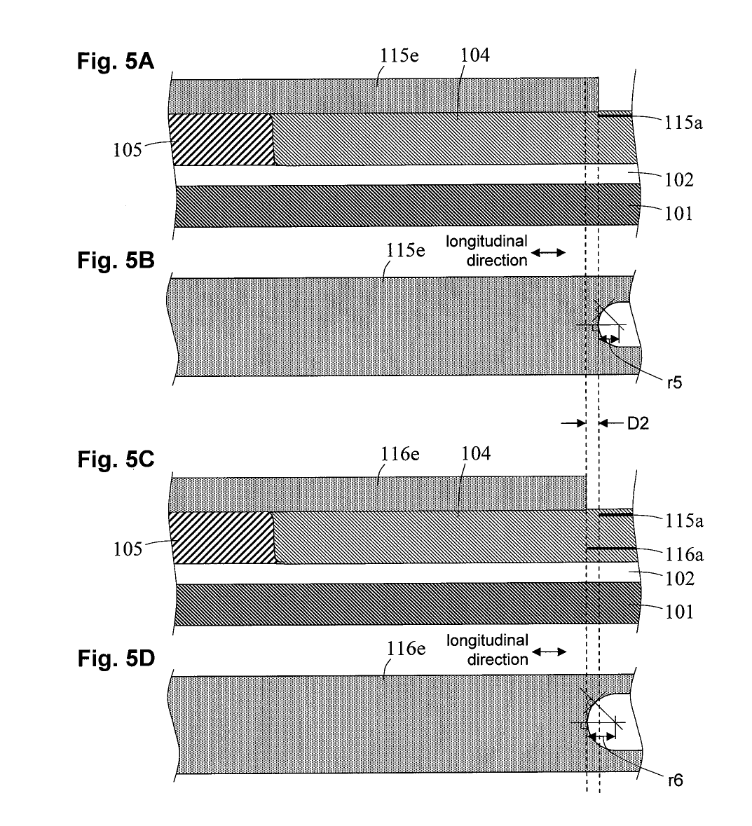

FIG. 5B is a plan view of the first resist film 115e shown in FIG. 4B. FIG. 5D is a plan view of the second resist film 116e shown in FIG. 4C. The transversal direction in FIGS. 5B and 5D corresponds to the longitudinal direction of the openings of the first resist film 115e and the second resist film 116e. The body region 105 is located a left side in FIGS. 5B and 5D. For easier understanding, FIG. 5A shows the cross-sectional view shown in FIG. 4B and FIG. 5C shows the cross-sectional view shown in FIG. 4C.

As shown in FIGS. 5B and 5D, corresponding to the third buffer region 115 and the fourth buffer region 116 to be formed, the openings of the first resist films 115 and the second resist film 116e are elongated towards the body region 105 and semicircular at the elongated, longitudinal end in a plane view. Furthermore, the opening of the second resist film 116e encompasses the opening of the first resist film 115e.

Furthermore, the longitudinal end of the opening of the second resist film 116e is shifted toward the body region 105 compared to the longitudinal end of the opening of the first resist film 115e. In FIGS. 5B and 5D, the longitudinal end of the opening of the second resist film 116e protrudes toward the body region 105 by a predetermined distance D2 compared to the longitudinal end of the opening of the first resist film 115e. The predetermined distance D2 in embodiments relating to the present invention is for example approximately 0.5 to 5 μm.

More specifically, a radius curvature (r6) of the semicircular portion of the opening of the second resist film 116e used in ion-implanting an N-type impurity at the high acceleration energy is larger than a radius curvature (r5) of the semicircular portion of the opening of the first resist film 115e used in ion-implanting at the low acceleration energy. The N-type impurity ion implantation with the low acceleration energy corresponds to the N-type impurity ion implantation in the vicinity of the surface of the SOI layer 103 corresponding to the buffer region 113. On the other hand, the N-type impurity ion implantation with the high acceleration energy corresponds to the N-type impurity ion implantation in the vicinity of the bottom of the SOI layer 103 corresponding to the buffer region 113.

Then, as shown in FIG. 4D, the structure is subject to high temperature heat treatment approximately at 1000° C. to 1250° C. for a predetermined period of time. Consequently, the N-type impurity in the third injection layer 115a and the fourth injection layer 116a is thermal-diffused uniformly in the vertical and transversal directions, whereby the third buffer region 115 corresponding to the third injection layer 115a and the fourth buffer region 116 corresponding to the fourth injection layer 116a are formed. The predetermined period of time is changed as appropriated according to a specification of the semiconductor device.

As a consequence of the high temperature heat treatment, the third buffer region 115 and the fourth buffer region 116 overlap one another and then they form a single buffer region 113. The third buffer region 115 reaches the uppermost surface of the SOI layer 103 and the fourth buffer region 116 reaches the surface of the buried oxide film 102. Furthermore, the N-type impurity concentration distribution in the single buffer region 113 extends from the top surface of the SOI layer 103 to the top surface of the buried oxide film 102. Furthermore, the interface between the buffer region 113 and the drift region 104 is shifted toward the body region 105 in the vicinity of the bottom of the buffer region 113 compared to that in the vicinity of the surface of the buffer region 113.

In FIGS. 4B and 4C, two different resist films are used and two different levels of N-type impurity acceleration energy are set. The N-type impurity is ion-implanted once at each acceleration energy level. Alternatively, the N-type impurity can be ion-implanted two or more times at the high acceleration energy using the second resist film 116e in order to adjust the N-type impurity concentration. Furthermore, the N-type impurity can be ion-implanted two or more times at the low acceleration energy using the first resist film 115e.

If the N-type impurity cannot be ion-implanted at the high acceleration energy because of limited ion implantation apparatus, as described in regard to the second embodiment, two levels of acceleration energy can be set within the range of the low acceleration energy and a difference between the two levels is increased to change the depth in the SOI layer 103 to which the N-type impurity is ion-implanted.

After the ion implantation, the structure can undergo high temperature heat treatment for example approximately at 1000° C. to 1250° C. for a longer period of time than the aforementioned predetermined period of time so that the N-type impurity concentration distribution in the buffer region 113 extends from the surface of the SOI layer 103 to the surface of the buried oxide film 102.

Furthermore, the openings of the first resist film 115e and the second resist film 116e are elongated toward the body region 105 and semicircular at the elongated, longitudinal end in a plane view. The radius curvature (r6) of the semicircular portion of the opening of the second resist film 116e is larger than the radius curvature (r5) of the semicircular portion of the opening of the first resist film 115e. The buffer region 113 is formed in accordance with the opening of the resist film. Therefore, as a result of such two resist films, the radius of curvature of the semicircular portion of the buffer region 113 is larger in the vicinity of the bottom than in the vicinity of the surface.

Reflecting this structure, in FIG. 4D, there are interface peaks protruding toward the body region 105 in the vicinity of the interface between the buffer region 113 and the drift region 104; one in the vicinity of the surface of the third buffer region 115 and the other in the vicinity of the bottom of the fourth buffer region 116 in the same manner as shown in FIG. 3C in regard to the second embodiment. Furthermore, an interface peak P4 in the vicinity of the bottom of the fourth buffer region 116 protrudes more toward the body region 105 than an interface peak P3 in the vicinity of the surface of the third buffer region 115. Here, in FIG. 4D, the interface peak P3 in the vicinity of the surface of the third buffer region 115 is a slightly sharp peak and the interface peak P4 in the vicinity of the bottom of the fourth buffer region 116 is a sharp peak.

In this structure, the N-type impurity concentration in the buffer region 113 is the lowest in a middle part. The middle part of the buffer region 113 corresponds to a contact portion between the third buffer region 115 and the fourth buffer region 116.

After the third buffer region 115 and the fourth buffer region 116 are formed, as shown in FIG. 4D, a first LOCOS oxide film 107a, a second LOCOS oxide film 107b, a gate oxide film 108 and a gate electrode 109 are formed. They are formed in the same manner as shown in FIG. 3C in regard to the second embodiment.

Then, as shown in FIG. 4E, after the gate electrode 109 and the like are formed, a collector region 114, an emitter region 106, an interlayer insulating film 110, an emitter electrode 111 and a collector electrode 112 are formed. They are formed in the same manner as shown in FIG. 3D in regard to the second embodiment.

In this way, the high voltage horizontal IGBT in an embodiment relating to the present invention is completed.

As described above, in the manufacturing method of the high voltage horizontal IGBT of this embodiment, a process of forming the buffer region starts with forming a first resist film having an opening corresponding to the buffer region on the surface of the SOI layer. The opening of the first resist film is elongated toward the body region and semicircular at the elongated, longitudinal end in a plane view. An N-type impurity is ion-implanted in the vicinity of the surface of the SOI layer using the first resist film. Then, a second resist film having an opening encompassing the opening of the first resist film is formed on the surface of the SOI layer. The longitudinal end of the opening of the second resist film is shifted toward the body region compared to the longitudinal end of the opening of the first resist film. The N-type impurity is ion-implanted in the vicinity of the bottom of the SOI layer using the second resist film.

The buffer region of the high voltage horizontal IGBT produced as described above extends from the surface of the SOI layer to the surface of the buried oxide film. The interface between the buffer region and the drift region is shifted toward the body region in the vicinity of the bottom of the buffer region compared to that in the vicinity of the surface of the buffer region. Therefore, as explained in regard to the first embodiment, the concentration of electric field in the vicinity of the bottom of the buffer region is moderated when a positive voltage in relation to the emitter electrode is applied to the collector electrode, allowing for a higher collector-emitter breakdown voltage. Furthermore, the buffer region of the high voltage horizontal IGBT is elongated toward the body region and semicircular at the elongated, longitudinal end in a plane view. The radius of curvature of the semicircular portion of the buffer region is larger in the vicinity of the bottom than in the vicinity of the surface. Therefore, the same efficacy as of the high voltage horizontal IGBT described in regard to the first embodiment is obtained.

The manufacturing method described in the third embodiment allows the structure of the high voltage horizontal IGBT to be easily reproduced compared to the manufacturing method described in the second embodiment. The manufacturing method in the second embodiment utilizes thermal diffusion to shift the interface between the buffer region and the drift region toward the body region in the vicinity of the bottom of the buffer region compared to that in the vicinity of the surface of the buffer region. On the other hand, the manufacturing method in the third embodiment utilizes two different resist films to control the position of ion-implanted N-type impurity. Therefore, the manufacturing method of the third embodiment ensures that the above interface is shifted toward the body region in the vicinity of the bottom of the buffer region compared to that in the vicinity of the surface of the buffer region. In other words, the manufacturing method in the third embodiment allows the structure of the high voltage horizontal IGBT in an embodiment relating to the present invention to be produced with accuracy.

The manufacturing method described in the third embodiment is an excellent manufacturing method because the structure of the high voltage horizontal IGBT in an embodiment relating to the present invention can easily be produced by utilizing two different resist films and appropriately changing the N-type impurity dose amount, acceleration energy and number of implantation operations so as to appropriately adjust the ion-implanted N-type impurity amount in the vicinity of the surface and in the vicinity of the bottom of the buffer region even if the SOI substrate has an SOI layer of a variant or large thickness.

In the second and third embodiments, the order of the ion implantation for introducing an impurity in the vicinity of the surface of the SOI layer and the ion implantation for introducing an impurity in the vicinity of the bottom of the SOI layer is not restricted to the above described order and can be selected on an arbitrary basis.

In the first to third embodiments, a high voltage horizontal IGBT is explained by way of example. The present invention is not restricted thereto. For example, the same efficacy as of these embodiments can be obtained for a buffer region at a drain region of a high voltage horizontal MOSFET formed on an SOI substrate, a buffer region at a cathode region of a high voltage diode and a buffer region at a drain region of a MOS transistor having a super junction structure.

For example, when the present invention is applied to a MOS transistor having a buffer region at a drain region, a structure will be as follows. Here, the above described buffer region of a high voltage horizontal IGBT corresponds to the drain region of a MOS transistor.

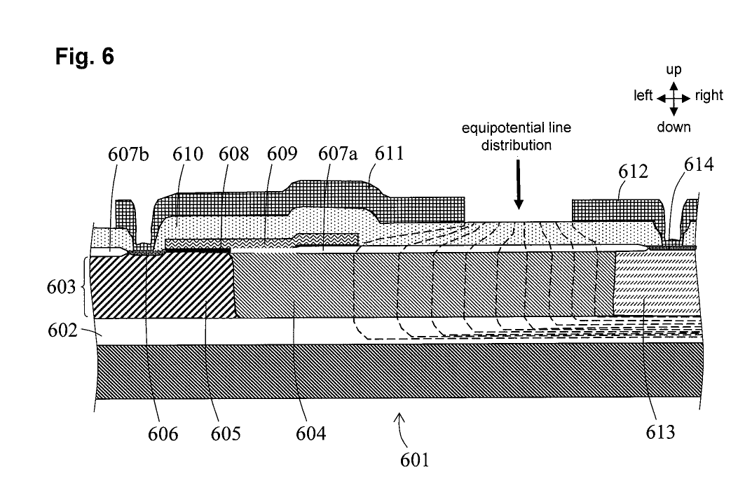

FIG. 6 is a cross-sectional view showing a MOS transistor. The vertical direction in FIG. 6 corresponds to the vertical direction of the MOS transistor and the transversal direction in FIG. 6 corresponds to the transversal direction of the MOS transistor. FIG. 6 is a schematic illustration in which scales in the vertical and transversal directions are not equal.

The MOS transistor comprises an SOI substrate 601, a body region 605 of a first conductivity type, a source region 606 of a second conductivity type, a drift region 604, a drain region 613, a drain contact region 614 and a gate electrode 609.

The SOI substrate 601 has a buried oxide film 602 and an SOI layer 603 of the first conductivity type formed on the buried oxide film 602. The body region 605 of the first conductivity type is formed in the SOI layer 603. The source region 606 of the second conductivity type that is an opposite conductivity type to the first conductivity type is formed in a surface portion of the body region 605. The drift region 604 that is a low concentration impurity region of the second conductivity type is formed in the SOI layer 603 next to the body region 605. The drain region 613 that is a high concentration impurity region of the second conductivity type is formed in the SOI layer 603 next to the drift region 604. The drain contact region 614 is formed in a surface portion of the drain region 613. The gate electrode 609 faces the body region 605 and is formed on the SOI layer 603 via a gate oxide film 608.

The drain region 613 of this semiconductor device extends from a surface of the SOI layer 603 to a surface of the buried oxide film 602. The interface between the drain region 613 and the drift region 604 is positioned equally in a vicinity of the bottom of the drain region 613 and in a vicinity of the surface of the drain region 613, or shifted toward the body region 605 in the vicinity of the bottom of the drain region 613 compared to that in the vicinity of the surface of the drain region 613.

In the same manner as in the structure of the high voltage horizontal IGBT explained in the first embodiment, the drain region 613 of this MOS transistor can also be elongated toward the body region 605 in a plane view. In this case, it is semicircular at the elongated, longitudinal end and a radius of curvature of the semicircular portion in the vicinity of the bottom of the drain region 613 can be equal to or larger than a radius of curvature of the semicircular portion in the vicinity of the surface of the drain region 613.

The semiconductor device manufacturing method explained in the second embodiment can be applied to a semiconductor device which is the above MOS transistor having a buffer region at a drain region. More specifically, in this manufacturing method of a semiconductor device, a process of forming the drain region is as follows. First, a resist film having an opening corresponding to the drain region is formed on a surface of a semiconductor layer. Then, an impurity is ion-implanted in a vicinity of a surface of the semiconductor layer using the resist film. Furthermore, an impurity is ion-implanted in a vicinity of a bottom of the semiconductor layer to a concentration higher than a concentration of impurity ion-implanted in the vicinity of the surface of the semiconductor layer.

The semiconductor device manufacturing method explained in the third embodiment can also be applied to a semiconductor device which is the above MOS transistor having a buffer region at a drain region. More specifically, in this manufacturing method of a semiconductor device, a process of forming the drain region is as follows. First, a first resist film having an opening corresponding to the drain region is formed on a surface of a semiconductor layer, the opening being elongated toward the body region and semicircular at the elongated, longitudinal end in a plane view. Then, an impurity is ion-implanted in a vicinity of a surface of the semiconductor layer using the first resist film. Then, a second resist film having an opening encompassing the opening of the first resist film and having a longitudinal end shifted toward a body region compared to a longitudinal end of the opening of the first resist film is formed on the surface of the semiconductor layer. Then, an impurity is ion-implanted in a vicinity of a bottom of the semiconductor layer using the second resist film.

The above described embodiments do not confine the technical scope of the present invention and, in addition to what is described above, various modifications and applications are available without departing from the technical idea of the present invention. For example, the order of processes in the above described embodiments is given by way of example and the processes can be performed in any order as long as an equivalent structure is obtained. Each process in the above described embodiments can be replaced with another equivalent process.

As described above, the present invention allows for a high breakdown voltage not only in a high voltage horizontal IGBT but also in a high voltage horizontal MOSFET, a high voltage diode and a MOS transistor having a super junction structure, and provides a useful semiconductor device and a semiconductor device manufacturing method.

What is claimed is:

1. A semiconductor device comprising:
an SOI substrate having an insulating layer and a semiconductor layer of a first conductivity type provided on the insulating layer;
a body region provided in the semiconductor layer and consisting of an impurity region of the first conductivity type;
an emitter region provided in a surface portion of the body region and consisting of an impurity region of a second conductivity type that is an opposite conductivity type to the first conductivity type;
a drift region provided in the semiconductor layer next to the body region and consisting of a low concentration impurity region of the second conductivity type;
a buffer region provided in the semiconductor layer next to the drift region and consisting of a high concentration impurity region of the second conductivity type;
a collector region provided in a surface portion of the buffer region and consisting of an impurity region of the first conductivity type; and
a gate electrode provided on the semiconductor layer via a gate insulating film and facing the body region and the drift region,
wherein the buffer region extends from a surface of the semiconductor layer to a surface of the insulating layer, and an interface between the buffer region and the drift region is positioned equally in a vicinity of a bottom of the buffer region and in a vicinity of a surface of the buffer region, or shifted toward the body region in the vicinity of the bottom of the buffer region compared to that in the vicinity of the surface of the buffer region.

2. A semiconductor device according to claim 1, wherein the buffer region is elongated toward the body region and semicircular at the elongated, longitudinal end in a plane view; and
a radius of curvature of the semicircular portion in the vicinity of the bottom of the buffer region is equal to or larger than a radius of curvature of the semicircular portion in the vicinity of the surface of the buffer region.

3. A manufacturing method of a semiconductor device including an SOI substrate having an insulating layer and a semiconductor layer of a first conductivity type provided on the insulating layer, a body region provided in the semiconductor layer and consisting of an impurity region of the first conductivity type, an emitter region provided in a surface portion of the body region and consisting of an impurity region of a second conductivity type that is an opposite conductivity type to the first conductivity type, a drift region provided in the semiconductor layer next to the body region and consisting of a low concentration impurity region of the second conductivity type, a buffer region provided in the semiconductor layer next to the drift region and consisting of a high concentration impurity region of the second conductivity type, a collector region provided in a surface portion of the buffer region and consisting of an impurity region of the first conductivity type, and a gate electrode provided on the semiconductor layer via a gate insulating film and facing the body region and the drift region, the manufacturing method comprising a step of forming the buffer region, the buffer region forming step comprising the steps of:
forming a resist film having an opening corresponding to the buffer region on a surface of the semiconductor layer;
ion-implanting an impurity in a vicinity of a surface of the semiconductor layer using the resist film; and
ion-implanting an impurity in a vicinity of a bottom of the semiconductor layer using the resist film to a concentration higher than a concentration of the impurity ion-implanted in the vicinity of the surface of the semiconductor layer.

4. A manufacturing method of a semiconductor device including an SOI substrate having an insulating layer and a semiconductor layer of a first conductivity type provided on the insulating layer, a body region provided in the semiconductor layer and consisting of an impurity region of the first conductivity type, an emitter region provided in a surface portion of the body region and consisting of an impurity region of a second conductivity type that is an opposite conductivity type to the first conductivity type, a drift region provided in the semiconductor layer next to the body region and consisting of a low concentration impurity region of the second conductivity type, a buffer region provided in the semiconductor layer next to the drift region and consisting of a high concentration impurity region of the second conductivity type, a collector region provided in a surface portion of the buffer region and consisting of an impurity region of the first conductivity type, and a gate electrode provided on the semiconductor layer via a gate insulating film and facing the body region and the drift region, the manufacturing method comprising a step of forming the buffer region, the buffer region forming step comprising the steps of:
forming a first resist film having an opening corresponding to the buffer region on a surface of the semiconductor layer, the opening being elongated toward the body region and semicircular at the elongated, longitudinal end in a plane view;
ion-implanting an impurity in a vicinity of a surface of the semiconductor layer using the first resist film;
forming a second resist film having an opening encompassing the opening of the first resist film and having a longitudinal end shifted toward the body region compared to the longitudinal end of the opening of the first resist film on the surface of the semiconductor layer; and
ion-implanting an impurity in a vicinity of a bottom of the semiconductor layer using the second resist film.

5. A semiconductor device comprising:
an SOI substrate having an insulating layer and a semiconductor layer of a first conductivity type provided on the insulating layer;
a body region provided in the semiconductor layer and consisting of an impurity region of the first conductivity type;
a source region provided in a surface portion of the body region and consisting of an impurity region of a second conductivity type that is an opposite conductivity type to the first conductivity type;
a drift region provided in the semiconductor layer next to the body region and consisting of a low concentration impurity region of the second conductivity type;
a drain region provided in the semiconductor layer next to the drift region and consisting of a high concentration impurity region of the second conductivity type;
a drain contact region provided in a surface portion of the drain region; and
a gate electrode provided on the semiconductor layer via a gate insulating film and facing the body region,
wherein the drain region extends from a surface of the semiconductor layer to a surface of the insulating layer, and an interface between the drain region and the drift region is positioned equally in a vicinity of a bottom of the drain region and in a vicinity of a surface of the drain region, or shifted toward the body region in the vicinity of the bottom of the drain region compared to that in the vicinity of the surface of the drain region.

6. A semiconductor device according to claim 5, wherein the drain region is elongated toward the body region and semicircular at the elongated, longitudinal end in a plane view; and
a radius of curvature of the semicircular portion in the vicinity of the bottom of the drain region is equal to or larger than a radius of curvature of the semicircular portion in the vicinity of the surface of the drain region.

7. A manufacturing method of a semiconductor device including an SOI substrate having an insulating layer and a semiconductor layer of a first conductivity type provided on the insulating layer, a body region provided in the semiconductor layer and consisting of an impurity region of the first conductivity type, a source region provided in a surface portion of the body region and consisting of an impurity region of a second conductivity type that is an opposite conductivity type to the first conductivity type, a drift region provided in the semiconductor layer next to the body region and consisting of a low concentration impurity region of the second conductivity type, a drain region provided in the semiconductor layer next to the drift region and consisting of a high concentration impurity region of the second conductivity type, a drain contact region provided in a surface portion of the drain region, and a gate electrode provided on the semiconductor layer via a gate insulating film and facing the body region, the manufacturing method comprising a step of forming the drain region, the drain region forming step comprising the steps of:
forming a resist film having an opening corresponding to the drain region on a surface of the semiconductor layer;
ion-implanting an impurity in a vicinity of a surface of the semiconductor layer using the resist film; and
ion-implanting an impurity in a vicinity of a bottom of the semiconductor layer using the resist film to a concentration higher than a concentration of the impurity ion-implanted in the vicinity of the surface of the semiconductor layer.

8. A manufacturing method of a semiconductor device including an SOI substrate having an insulating layer and a semiconductor layer of a first conductivity type provided on the insulating layer, a body region provided in the semiconductor layer and consisting of an impurity region of the first conductivity type, a source region provided in a surface portion of the body region and consisting of an impurity region of a second conductivity type that is an opposite conductivity type to the first conductivity type, a drift region provided in the semiconductor layer next to the body region and consisting of a low concentration impurity region of the second conductivity type, a drain region provided in the semiconductor layer next to the drift region and consisting of a high concentration impurity region of the second conductivity type, a drain contact region provided in a surface portion of the drain region, and a gate electrode provided on the semiconductor layer via a gate insulating film and facing the body region, the manufacturing method comprising a step of forming the drain region, the drain region forming step comprising the steps of:
forming a first resist film having an opening corresponding to the drain region on the surface of the semiconductor layer, the opening being elongated toward the body region and semicircular at the elongated, longitudinal end in a plane view;
ion-implanting an impurity in a vicinity of a surface of the semiconductor layer using the first resist film;
forming a second resist film having an opening encompassing the opening of the first resist film and having a longitudinal end shifted toward the body region compared to the longitudinal end of the opening of the first resist film on the surface of the semiconductor layer; and
ion-implanting an impurity in a vicinity of a bottom of the semiconductor layer using the second resist film.
